(19) United States
(12) Patent Application Publication
(10) Pub. No.: US 2021/0351151 A1
(43) Pub. Date: Nov. 11, 2021

(54) Circuit Carrier Having an Installation Place for Electronic Components, Electronic Circuit and Production Method

(71) Applicant: Siemens Aktiengesellschaft, München (DE)

(72) Inventors: Robby Urbahn, Wust-Fischbeck (DE); Matthias Heimann, Potsdam (DE); Christian Schellenberg, Potsdam (DE); Klaus Wilke, Berlin (DE)

(73) Assignee: Siemens Aktiengesellschaft, München (DE)

(21) Appl. No.: 17/268,296

(22) PCT Filed: Aug. 20, 2019
(86) PCT No.: PCT/EP2019/072203

§ 371 Date: Feb. 12, 2021

(30) Foreign Application Priority Data
Aug. 31, 2018 (EP) 18192039.8

(51) Int. Cl. H01L 23/00; H05K 1/11; H05K 1/18; H05K 3/30

(52) U.S. Cl. CPC H01L 24/26; H05K 3/0044; H01L 24/83; H05K 1/119; H05K 1/181; H05K 3/305; H01L 24/32; H01L 24/30; H01L 2224/33181; H01L 2224/26175; H01L 2224/30505; H01L 2224/32227; H01L 2224/33183; H01L 2224/33104; H01L 2224/83815; H01L 2224/8384; H01L 2224/83192; H01L 2224/83951; H05K 2201/09036; H05K 2201/10977; H05K 2203/1178; H01L 24/33

(57) ABSTRACT

Various embodiments include a circuit carrier comprising: an installation place for an electronic component; and a deposit of a joining adjuvant applied to the installation place. The installation place has at an edge, a recess forming a depression in a surface of the circuit carrier. The deposit comprises a sintered material with a protuberance at an edge of the deposit.

### CROSS-REFERENCE TO RELATED APPLICATIONS

This application is a U.S. National Stage Application of International Application No. PCT/EP2019/072203 filed Aug. 20, 2019, which designates the United States of America, and claims priority to EP Application No. 18192039.8 filed Aug. 31, 2018, the contents of which are hereby incorporated by reference in their entirety.

### TECHNICAL FIELD

The present disclosure relates to electronics. Various embodiments include circuit carriers having an installation place for an electronic component, electronic circuits having such a circuit carrier, methods for producing a circuit carrier in which an installation place for an electronic component is produced, and/or methods for producing an electronic assembly in which such a circuit carrier is used.

### BACKGROUND

Circuit carriers and electronic circuits are used in many products. In particular, power electronic circuits are, for example, used in rectifiers and converters. For making good thermal and electrical contact with power semiconductors in such power electronic circuits, care must be taken that their function is provided unrestrictedly. The good thermal and electrical properties with, at the same time, a low overall height must be ensured by the contact structure. In the event of a reduction in the overall height, however, the use of an insulating medium, primarily around the outer sides of the power component, is additionally required.

In particular in the case of making planar chip-top-side contacts of power semiconductors, these regions of the chip edges and the adjacent passivated power regions on the chip have to be filled with the insulating medium. For satisfactory insulation, it is necessary that this filling is carried out without bubbles. However, this represents a technical demand. The insulating material, which is also designated as an underfill material, must ensure that during the filling, gassing out from the joining zone to the outside takes place and no bubbles form in the underfill material. In particular in sintered joining zones, which are highly suitable for a thermal structure, gassing out during the filling frequently leads to bubbles. The following underfill materials, for example, are used as filling materials: epoxy resins optimized for underflow, with and without fillers.

### SUMMARY

The teachings of the present disclosure describe circuit carriers having an installation place for electronic components and an electronic circuit having such a circuit carrier in which the possibility of bubble-free filling with an underfill material is improved, methods for producing such a circuit carrier, and/or methods for producing such an electronic assembly. Bubble-free filling with underfill material is supported. For example, some embodiments include a circuit carrier (12) having an installation place (14) for an electronic component (13), characterized in that the installation place (14) has at its edge at least one recess (22) which forms a depression in the surface (27) of the circuit carrier (12), and in that a deposit (16) of a joining adjuvant is applied to the installation place (14), wherein the deposit (16) consists of a sintered material and a protuberance (23) is provided at the edge of the deposit (16).

In some embodiments, the recess (22) consists of a slot, which extends at right angles to the edge of the installation place (14).

In some embodiments, the depression is provided in an insulating layer (15) forming the surface (27) of the circuit carrier (12) and/or in a metallization (26) on the circuit carrier (12).

In some embodiments, the protuberance (23) has the form of a wedge which projects from the edge of the deposit (16).

In some embodiments, the width of the wedge corresponds exactly to the height of the deposit (16).

In some embodiments, an electronic circuit (11) having a circuit carrier (12) as described above and an electronic component (13), characterized in that the electronic component (13) is fixed to the deposit of the joining adjuvant.

In some embodiments, a gap between the circuit carrier (12) and the component (13) is filled with an underfill material (19).

As another example, some embodiments include a method for producing a circuit carrier (12), in which an installation place (14) for an electronic component (13) is produced, characterized in that at least one recess (22) is produced at the edge of the installation place (14), said recess being formed as a depression in the surface (27) of the circuit carrier (12), or surface structuring is produced.

In some embodiments, the recess (22) is produced by a material-removing method.

In some embodiments, the recess (22) or surface structuring is produced by structuring a layer on the circuit carrier (12).

In some embodiments, a deposit (16) of a joining adjuvant is applied on or to the installation place (14).

As another example, some embodiments include a method for producing an electronic assembly, characterized in that a circuit carrier (12) is produced by a method as claimed in claim 11, an electronic component (13) is fixed to the deposit (16), and a gap (18) between the circuit carrier (12) and the component (13) is filled with an underfill material (19).

In some embodiments, the underfill material (19) is introduced into the gap (18) in a region outside the at least one recess (22), e.g. exactly in the center between two recesses (22).

### BRIEF DESCRIPTION OF THE DRAWINGS

The exemplary embodiments explained below are embodiments of the teachings herein and do not limit the scope of those teachings. In the exemplary embodiments, the components of the embodiments that are described each represent individual features to be considered independently of one another, which each also develop the disclosure independently of one another and are therefore also to be viewed as a potential constituent part, individually or in a combination other than that shown. Furthermore, the embodiments described can also be supplemented by further features that have already been described.

FIG. 1 shows an exemplary embodiment of the electronic assembly incorporating teachings of the present disclosure with an exemplary embodiment of the circuit carrier according to the invention as a sectional image;

FIG. 2 shows the top view of an exemplary embodiment of the circuit carrier incorporating teachings of the present disclosure;

FIGS. 3 and 4 show exemplary embodiments of different recesses and protuberances in the electronic assembly according to FIG. 1;

FIGS. 5 to 7 show further exemplary embodiments of recesses of the circuit carrier incorporating teachings of the present disclosure;

FIG. 8 shows a metallization having recesses as an exemplary embodiment of the circuit carrier incorporating teachings of the present disclosure as a top view;

FIG. 9 shows the circuit carrier according to FIG. 8 with a sintering paste deposit put in place as a top view; and

FIG. 10 shows a mask with which the exemplary embodiment of the sintering paste deposit according to FIG. 9 can be printed.

### DETAILED DESCRIPTION

In some embodiments, a circuit carrier includes an installation place which has at its edge at least one recess or surface structuring which forms a depression in the surface of the circuit carrier. Surface structuring is understood as an adaptation of the surface to the extent that this is used as a flow obstacle for the underfill material. This can be achieved, for example, by the surface being roughened, for example with a laser. The fact that the surface structuring provides a different surface means that this constitutes a flow obstacle for the underfill material. In some embodiments, this is achieved by a more difficult wettability of the structured surface as compared with the remainder of the surface of the circuit carrier or the layers located thereon. In the following text, the advantages of the teachings herein will each be explained by using the recesses. However, this is of course analogously true also when the surface structuring is used.

The introduction of a recess which is formed as a depression, allows, when filling the gap between the component and the circuit carrier that the recess remains free from underfill material for longer than the remainder of the gap between the component and the circuit carrier. In this way, there is the possibility that outgassings during the filling escape from this joining gap (gap for short below) through the depression, while the underfill material propagates in the gap. In the process, the underfill material forms a flow front. The recess is arranged at the edge of the installation place in such a way that the flow front can flow toward this gap. Therefore, the recess is only closed by the underfill material at the end, so that the recess is able to transport the outgassings to the outside until the end. The formation of bubbles may therefore be avoided.

The edge of the installation place is defined by the outer edge of the component to be installed. In other words, during the design of the installation place on the circuit carrier, it is necessary to take into account the dimensions of the component which is to be mounted. The recess then has to be provided in the circuit carrier in the region of the imaginary outer edge of the component. For example, this can be done in such a way that part of the recess lies within the installation place and part of the recess lies outside the installation place. In this way, a type of channel or “tunnel” for the outgassings is produced, while the underfill material is distributed in the gap.

In the interests of direct thermal conduction and a low overall height, the gap may be chosen to be as narrow as possible. In particular when a sintered material is used as a contact-making material, very narrow gaps can be implemented. In conventional contact deposits made of sintered material, this gap can lie, for example, in a range from 20 μm to 100 μm.

The installation places are normally rectangular or square in their basic shape, e.g., also U-shaped. In some embodiments, the recesses are arranged at the edge of the old installation place in such a way that these are located in the center between the corners of the installation place. Underfilling of the gap can then be carried out starting from the corners, so that the flow fronts move from the corners of the installation place toward the recesses and fill the recesses at the end. If, here, the flow front should reach the recess more quickly from one corner than from the other corner, the recess represents a flow obstacle, since the underfill material must overcome a resistance in order to overcome the edge of the recess, that is to say the edge of the depression forming the recess. In this way, the recess remains open for outgassing for a longer time and closes only when the flow fronts of the underfill material meet at the recess from opposite directions. The result is to achieve a bubble-free or at least largely bubble-free underfilling result.

Of course, it is also possible to provide the recesses in the corners. In this case, the filler may flow from the center of the one installation place toward the corners, if these enclose the center of the one installation place.

In some embodiments, the recess consists of a slot or a circular opening, which extends at right angles to the edge of the installation place.

In some embodiments, the recess at the edge of the installation place extends through the imaginary edge of the assembly, so that the recess can transport outgassings from the installation place to the outside. A slot which extends at right angles to the edge of the installation place can be located on the other side and this side of the edge of the installation place and therefore fulfills this object particularly well. In addition, such a slot can be produced simply, for example by micro-milling or laser machining. In some embodiments, a subtractive etching process, for example by means of photolithographic structuring, is also conceivable as a fabrication method.

In some embodiments, the depression may be provided in an insulating layer forming the surface of the circuit carrier, in particular consisting of a solder stop varnish, and/or in a metallization on the circuit carrier. If the depression, for example the slot, is produced in the surface of the circuit carrier, all the layers of the layer structure of the circuit carrier are available for its formation. The insulating layer is normally brought up to the installation place and ends at a specific distance from the installation place, in order that the latter can be reliably kept free of insulating material. If this layer consists of a solder stop varnish, for example, this is usually developed photochemically. Here, the recesses can be taken into account from the start and formed in situ with the solder stop layer with the production.

In some embodiments, the metallization on the circuit carrier is used for the production of the recess. The metallization is also applied to the circuit carrier as a layer and is structured to form contact pads and conductor tracks. During this structuring process (for example by etching technology), the depression can be produced in situ during the processing. Of course, it is also possible to provide other fabrication methods for the recess. Both in the insulating layer and in the metallization, the recesses can be formed, for example, by means of micro-milling or laser machining. These methods have the advantage of very high accuracy, so that the recesses can be produced precisely. In particular, the sharp edges of the depression which are required to stop the flow front of the underfill material can be produced excellently by these methods. In addition, it is possible also to produce recesses which reach down into the material of the circuit carrier by means of milling or laser machining. Deeper recesses have the advantage that outgassings can be transported still more reliably to the outside.

In some embodiments, a deposit of a joining adjuvant, in particular of a sintered material, may be applied to the installation place. If the joining adjuvant is already provided on the circuit carrier, this makes the mounting of the component easier. For mounting purposes, the circuit carrier is usually already provided with joining adjuvant. Here, this can be solder material which, for example, is applied as a paste by means of mask technology. If printing errors which lead to filling of the recesses occur during this process, this can be determined optically before the mounting of the components, so that a rejection or a correction of this error can be carried out in good time.

The deposit can also consist of a sintered material. This can likewise be printed from sintering paste. Here, that specified above relative to the application of solder material applies accordingly. In some embodiments, preforms (protuberances) can also be used, which can advantageously be produced particularly precisely. These are fixed in the installation place or laid on directly before the mounting of the component.

In some embodiments, the deposit may consist of sintered material, a protuberance being provided at the edge of the deposit. If the deposit consists of a sintered material, it is possible to provide protuberances which have a comparatively fine geometry. This is because the sintered deposits substantially maintain their shape during the joining (if shrinkage is disregarded), so that these fine structures are maintained. This is different in the case of solder materials, which are melted to produce the connection. Here, fine protuberances would be lost because of the surface tension of the liquid solder material.

In some embodiments, the protuberances support the outward conduction of outgassing during the filling of the gap with underfill material. Here, the protuberances are given the task of directing the underfill material in a specific direction when the latter arrives with its flow front at the protuberance, so that, for example, it is possible to prevent said underfill material from getting into regions in which bubbles can be enclosed. In some embodiments, the protuberances can also be used in such a way that the flow front is directed toward a flow obstacle such as a recess in the shape of a depression (more on this below). The recesses, which provide an edge of the depression as a flow obstacle, then lead to the flow front being stopped until the recess is also filled with underfill material at the end. Until then, the recess can be used as a channel for transporting outgassings.

However, even without the additional action of the recesses, by diverting the flow fronts or stopping the flow fronts, the protuberances can prevent underfill material which, for example, fills the gap from different corners of an installation place, from flowing together too early, and thus would prevent outgassing with the consequence of bubble formation.

If square or rectangular installation places are assumed, the protuberances can be arranged in the center between two corners in each case. This means that the likewise rectangular deposit of sintered material is likewise rectangular or square and each has the protuberance in the center between the corners.

In the sense of the disclosure, a protuberance is to be understood as a structure which projects from the edge of the deposit of sintered material and thus forms an obstacle which stops or deflects an underfill material flowing along the deposit.

In some embodiments, the protuberance has the form of a wedge which projects from the edge of the deposit. A wedge-shaped protuberance is arranged such that the wedge, so to speak, lies on its triangular surface. In other words, the wedge-shaped protuberance can be imagined as a prism with a triangular base, wherein this prism adjoins the deposit with one of its side surfaces.

In some embodiments, the width of the wedge may correspond exactly to the height of the deposit.

In some embodiments, the wedge fills the gap over its entire gap height. Since the gap width is given by the height of the sintered deposit, however, this is the case only when the width of the wedge corresponds exactly to the height of the deposit. In this way, the deflecting function of the protuberance may be used most effectively. In addition, such a protuberance which corresponds to the height of the sintered deposit can be produced most simply. Here, use is made of a mask which has a mask opening containing the protuberance, wherein the filling of this mask opening, besides the deposit of sintered material, simultaneously produces the protuberance at the same height.

Of course, the protuberance can also have geometries other than that of a wedge. These can, for example, also be cube-shaped, wherein the cube, so to speak, adjoins the side of the deposit of sintering paste. Here, too, the cube may have the same height as the deposit. In some embodiments, the protuberance having the shape of a half-cylinder, which adjoins the deposit of sintering paste with its flat side surface. Here, too, the height of this half-cylinder may correspond to the height of the deposit.

In some embodiments, the circuit carrier is formed as described above, wherein the electronic component is fixed to the deposit of the joining adjuvant.

The electronic circuit is an implementation in which the circuit carrier which has already been explained thoroughly above is used for the end product. If such an electronic assembly is underfilled with underfill material, bubble-free underfilling results can be achieved as a result, by which means the above object is achieved. The bubble-free underfill material may improve both the thermal conduction and also the electrical insulation in the electronic assembly.

In some embodiments, a gap between the circuit carrier and the component may be filled with an underfill material.

In some embodiments, at least one recess is produced at the edge of the installation place, said recess being formed as a depression in the surface of the circuit carrier. If a recess is produced, then the product produced, namely the circuit carrier, can be used to produce the electronic assembly explained above. The advantages associated herewith have already been recited and are not to be mentioned again at this point.

In some embodiments, the recess may be produced by a material-removing method, in particular by milling or drilling. As already explained, material-removing methods such as, for example, micro-milling or drilling permit particularly high accuracies. In particular, the necessary edges which form the edge of the depression can be formed with sharp edges in the recesses.

During milling, elongated recesses can be produced. Depending on whether the axis of rotation of the milling head is at right angles or parallel to the surface of the circuit carrier, the elongated recesses can have a sharp edge all round or a tapering edge at their ends. The tapering edge at the end of the recesses can be used as a flow aid in order that the recess is still filled with underfill material at the end of the underfilling process.

In some embodiments, the recess may be produced by structuring a layer, in particular by structuring an insulating layer on the circuit carrier. As already mentioned, it is also possible to produce recesses by structuring the layer. This fabrication method lies in the fact that the structuring must be carried out anyway and here no additional fabrication outlay arises for the formation of the recesses.

In some embodiments, a deposit of a joining adjuvant may be applied on or to the installation place. As already mentioned, the deposits of the joining adjuvant, in particular the sintered material, can be applied to the circuit carrier before the mounting of the electronic components. The quality of this intermediate result (before the mounting of the deposit) can then be assessed before final mounting is carried out.

In some embodiments, a circuit carrier is produced by a method as described above, wherein:
an electronic component is fixed to the deposit,
a gap between the circuit carrier and the component is filled with an underfill material.

The details of the mounting method for the electronic assembly have already been explained thoroughly. In some embodiments, it is necessary to apply the deposits (possibly provided with additional protuberances) to the circuit carrier, wherein the electronic components are placed on the latter for the purpose of final mounting. The gap is then filled with the underfill material wherein, as already explained, a bubble-free underfilling result can be achieved.

In some embodiments, the underfill material may be introduced into the gap in a region outside the at least one recess, preferably exactly in the center between two recesses.

The underfill material may expand uniformly toward both sides when it is introduced in the center between two recesses. Should this not be the case, the recesses serve as a flow obstacle in order to eliminate these non-uniformities. Therefore, reliable gassing-out is easily possible. If, as already mentioned, a square or rectangular installation place is provided and the recesses are provided in the center of the side edges, then the center between the recesses is normally located in the corners (in the case of square installation places or close to the corners even in rectangular installation places).

Further details of the teachings herein will be described below by using the drawings. The same or mutually corresponding drawing elements are each provided with the same designations and will be explained repeatedly only to the extent to which differences between the individual figures result.

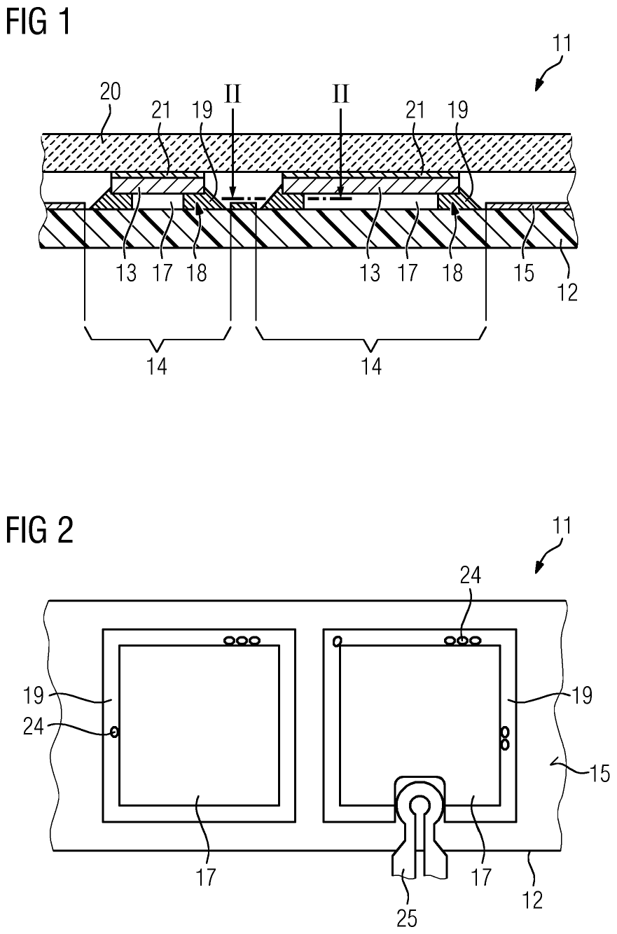

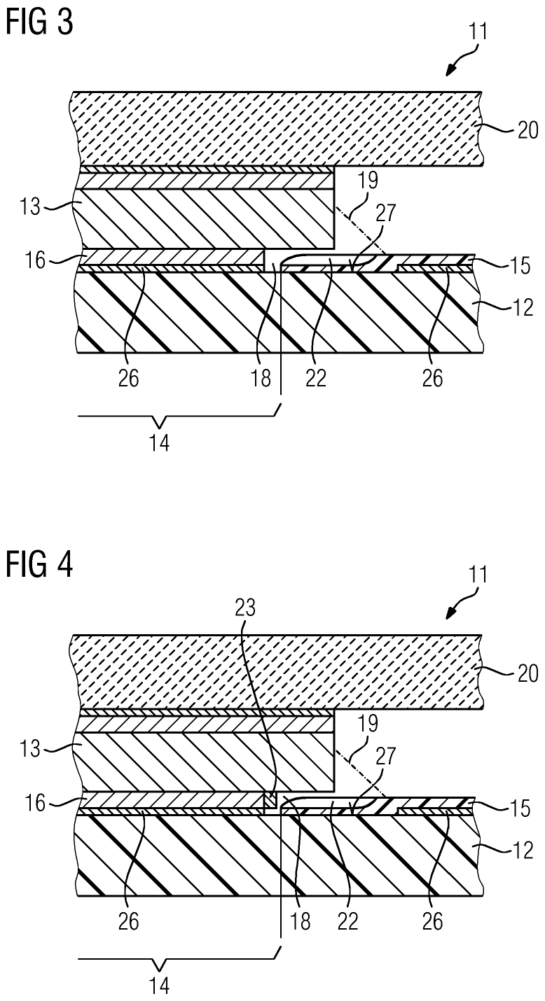

According to FIG. 1, an electronic circuit 11 which has a circuit carrier 12 and electronic components 13 is illustrated. The electronic components 13 are each provided on installation places 14 of the circuit carrier 12. The installation place 14 is produced by openings being formed in an insulating layer 15 made of a solder stop varnish. In each of these openings, a deposit 16 provided on the surface of the circuit carrier 12 (see, for example, FIG. 3) has in each case been remelted to form a sintered connection 17. A remaining gap 18 is filled with an underfill material 19, which closes the gap between the component 13 and the circuit carrier 12. In addition, the electronic circuit 11 has a top plate 20, on which a connection to the respective top sides of the components 13 is respectively made via a further sintered connection 21.

In FIG. 1, the electronic circuit 11 is illustrated without any recesses 22 or protuberances 23 (however, see FIGS. 3 to 7). The protuberances and recesses illustrated in these figures can, however, be located in front of or behind the section plane which is illustrated in FIG. 1. To this extent, the variants according to their aforementioned figures can be introduced into the electronic circuit 11 according to FIG. 1.

However, FIG. 1 also shows a structure such as the latter would appear according to the prior art without any recesses and protuberances. Such a structure was produced for test purposes, wherein this structure has been sectioned in the section plane II-II according to FIG. 1. In this section plane, it is possible to see a polished surface, which is formed by the sintered connection 17. This sintered connection 17 is surrounded by the underfill material 19. Since the electronic circuit 11 according to FIG. 2 has been produced without recesses and protuberances, during the potting of the gap 18 (cf. FIG. 1) bubbles 24 have arisen in the underfill material, which have their origin as a result of gassing-out of the sintered connection 17. This bubble formation is to be prevented by the protuberances and recesses taught herein.

In FIG. 2, contact structures 25 can likewise be seen, which are used as conductor tracks for making contact with the electronic component 21 not illustrated in FIG. 2 (cf. FIG. 1).

FIG. 3 illustrates a detail from the electronic assembly, which can be constructed according to FIG. 1. The detail represents an edge of the recess 14, in which the component 13 can also be seen. However, as distinct from FIG. 1, the edge of the recess 14 is formed by the insulating layer 15 underneath the component 13. However, the insulating layer 15 does not reach as far as the deposit 16 of a sintered material which has been applied to a contact layer and which is part of a structured metallization 26. The metallization 26 and the insulating layer 15 are each located on the surface 27 of the circuit carrier 12.

In addition, according to FIG. 3, it is possible to see the recess 22 which has been introduced into the insulating layer 15. This has been done by a micro-mill, which can be seen from the fact that the recess 22 tapers toward the outside. The recess therefore consists of a slot in the insulating layer 15, through which the section of FIG. 3 extends in the longitudinal direction. In some embodiments, the slot could also have been produced by an etching process or laser machining, for example.

According to FIG. 3, it is also possible to see the protuberance 23, which is connected to the deposit 26 and, for example, can be wedge-shaped, in the shape of a half-cylinder or in the shape of a cube. As can be gathered from FIGS. 5 to 7, this protuberance 23 in each case adjoins the outer side in the center of the deposit 16 and projects from the latter (hence the term protuberance). The sintered deposits 16 have the advantage that this protuberance is also maintained following the thermal treatment for the purpose of joining the sintered connection, since the sintered bodies which form the deposit 16 remain dimensionally stable during the joining.

In FIGS. 5 to 7, it is also possible to gather the respective geometry of the protuberances. These have the height of the deposit 16 and are each connected to the outer edges. According to FIG. 5, the protuberance consists of a wedge. In other words, the latter is a three-cornered prism, wherein this adjoins the outer side of the deposit 16 with one of its three side surfaces and thus projects with the opposite tip away from the side edge. The base surface and the top surface of this prism are therefore on the plane of the underside and the upper side, respectively, of the deposit 16.

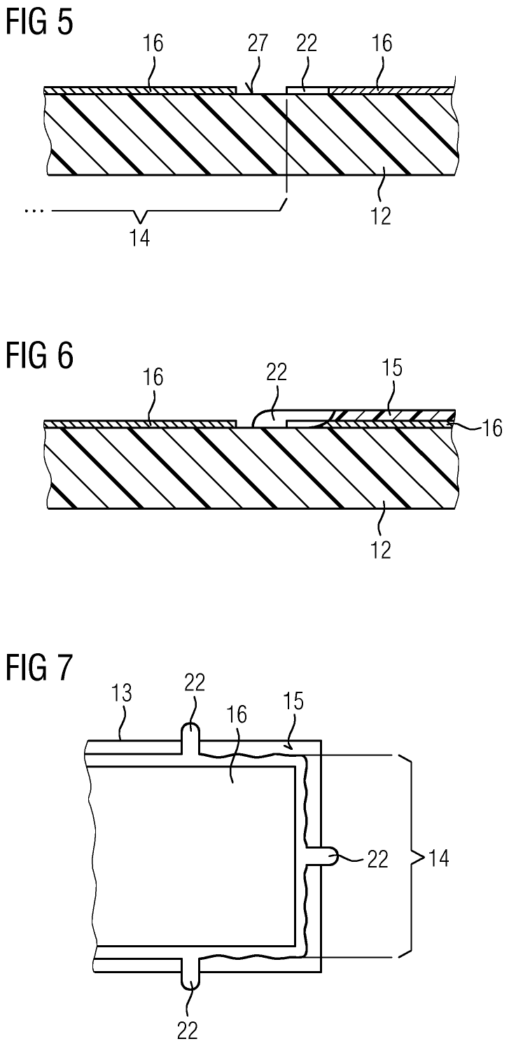

According to FIG. 6, the protuberance is formed as a half-cylinder, wherein the latter projects with the part of the round lateral surface away outward and lies with the straight sectional surface on the side surface of the deposit 16. The base surface and top surface are therefore again each on one plane with the upper side and the underside of the deposit 16.

According to FIG. 7, the protuberance 23 is cube-shaped, with one of the lateral surfaces of this cube lying on the lateral surface of the deposit 16. The upper and the lower side of the cube each form a common surface with the upper side and the underside of the deposit 16.

According to FIG. 4, a variant of the electrical circuit 11 according to FIG. 3 is illustrated, which differs only in the fact that both a protuberance 23 and a recess 22 are jointly used.

If the gap 18 is filled with the solder material, then both the recess 22 and the protuberance 23 both act in their way to conduct the underfill material 19. The latter flows in each case from the corners of the component 13 (these are each located in front of and behind the sectional plane according to FIGS. 3 and 4) toward the protuberance 23 and recess 22, both in the exemplary embodiment according to FIG. 3 and in the exemplary embodiment according to FIG. 4.

This flow direction lies at right angles to the plane of the drawing. By means of the protuberance 23, this flow is then diverted to the right in the illustration according to FIGS. 3 and 4, this flow then running parallel to the plane of the drawing. Here, the recess 22 represents a flow barrier, at least for the flow direction at right angles to the lateral plane, so that the underfill material first comes to a standstill at this barrier and outgassings from the deposit 16 can penetrate into the open unimpededly. Only when the flow front has extended inward from the outer corners or edges of the component 13 in the gap 18 is it directed into the gap by the protuberance 23, so that said gap can be filled from inside to outside (from left to right in this drawing). However, this takes place firstly before the gap 18 has been filled with underfill material all round, so that bubble formation can be avoided.

According to FIGS. 5 to 7, further configurations for the recesses 22 are illustrated. These can be combined in the electronic assemblies 11, which are illustrated in the other figures. According to FIG. 5, the protuberance consists of structuring of the insulating layer 15. This structuring can be produced, for example, at the same time as the formation of the installation place 14. The insulating layer 15 is located directly on the surface 27 of the substrate 12, since in this region the metallization 26 of the surface 27 has been removed.

According to FIG. 6, the recess 22 is produced by micro-milling. As distinct from what is illustrated in FIG. 3, this recess is not, however, located only in the insulating layer 15 but also in the metallization 26 which, in this case, is still present underneath the insulating layer 15. In this way, in relation to the thickness of the insulating layer 15 and of the metallization 26, advantageously greater gap depths can be achieved, since the latter can be provided in both layer regions. Greater gap depths also advantageously represent an obstacle to the flowing underfill material that is more difficult to overcome.

FIG. 7 illustrates the location at which the recesses 22 can be provided. The installation place 14 is illustrated from above, wherein it is also possible to see that the front of the solder stop varnish which forms the insulating layer 15 is formed somewhat irregularly (illustrated exaggeratedly in FIG. 7). The recesses 22 in this case have been produced by a laser, which explains the round ends of the groove produced. In addition, in FIG. 7 it is possible to see the outer contour of the component 13 which, however, is only put on later.

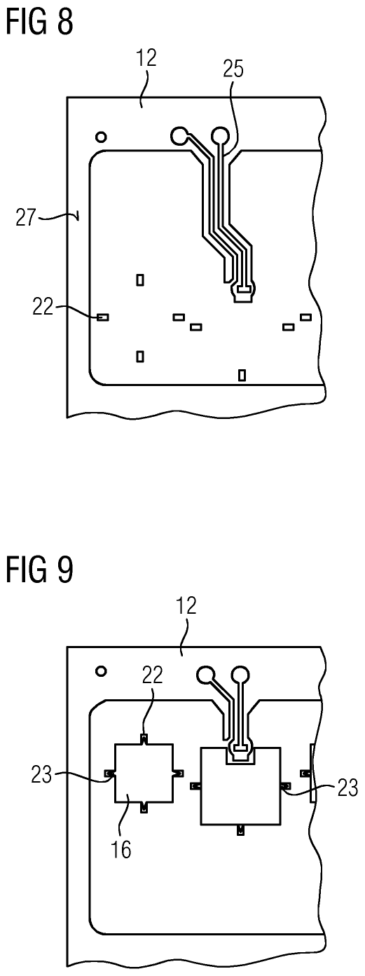

In FIG. 8, the circuit carrier 12 can be seen with a metallization which, in addition to the contact structures 25, also has the recesses 22. The recesses required for this purpose can be produced in the metallization by etching, for example. For this purpose, it is necessary to use a printing mask, which forms a negative form of the metal structures illustrated in FIG. 3. In other words, such a mask has etching openings everywhere where, according to FIG. 8, the surface 27 of the circuit carrier 12 is revealed.

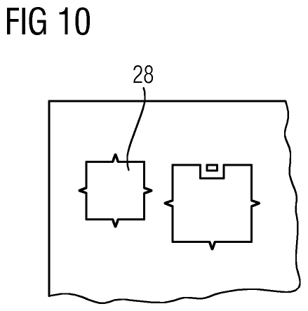

In FIG. 9, it is illustrated how the deposits 16 of sintering paste have been applied to the circuit carrier 12 according to FIG. 8. Here, it is also possible to see that the protuberances 23 correspond to the recesses 22, so that the effect described in relation to FIG. 4 of a diversion of the underfill material can be achieved. In addition, it can be seen that the deposits 16 of sintering paste for some components consist of multiple segments, in order to ensure different contacts of the electronic component to be joined (not illustrated in FIG. 9).

According to FIG. 10, a printing stencil is illustrated, which has mask openings 28 at the points at which the deposits 16 according to FIG. 9 are to be printed. It is possible to see that the protuberances 23 according to FIG. 9 are implemented by indentations 29 in the mask openings 28. These are filled with the material, for example the sintering paste, during the printing, in order that the deposits 16 have the protuberances 23.

### LIST OF DESIGNATIONS

11 Electronic circuit

12 Circuit carrier

13 Electronic components

14 Installation places

15 Insulating layer

16 Deposit

17 Sintered connection

18 Gap

19 Underfill material

20 Top plate

21 Further sintered connection

22 Recesses

23 Protuberances

24 Bubbles

25 Contact structures

26 Metallization

27 Surface

28 Mask openings

29 Indentations

What is claimed is:

1. A circuit carrier comprising:
an installation place for an electronic component;
wherein the installation place has at an edge, a recess forming a depression in a surface of the circuit carrier; and
a deposit of a joining adjuvant applied to the installation place;
wherein the deposit comprises a sintered material with a protuberance at an edge of the deposit.

2. The circuit carrier claimed in claim 1, wherein the recess comprises a slot, extending at right angles to the edge of the installation place.

3. The circuit carrier as claimed in claim 1, wherein the depression is formed in an insulating layer on the circuit carrier and/or in a metallization on the circuit carrier.

4. The circuit carrier as claimed in claim 1, wherein the protuberance comprises a wedge projecting from the edge of the deposit.

5. The circuit carrier as claimed in claim 4, wherein a width of the wedge corresponds exactly to a height of the deposit.

6. An electronic circuit comprising:
an installation place for an electronic component;
wherein the installation place has at an edge, a recess forming a depression in a surface of the circuit carrier; and
a deposit of a joining adjuvant applied to the installation place;
wherein the deposit comprises a sintered material with a protuberance at an edge of the deposit;
wherein the electronic component is fixed to the deposit of the joining adjuvant.

7. The electronic circuit as claimed in claim 6, wherein a gap between the circuit carrier and the component is filled with an underfill material.

8. A method for producing a circuit carrier, the method comprising:
forming an installation place for an electronic component including producing a recess at an edge of the installation place;
wherein the recess comprises a depression in a surface of the circuit carrier or a surface structure.

9. The method as claimed in claim 8, wherein the recess is produced by a material-removing method.

10. The method as claimed in claim 8, wherein the recess or surface structuring is produced by structuring a layer on the circuit carrier.

11. The method as claimed in claim 8, further comprising depositing a joining adjuvant is applied on or to the installation place.

12. A method for producing an electronic assembly, the method comprising:
producing a circuit carrier by a method as claimed in claim 11;
fixing an electronic component to the deposit; and
filling a gap between the circuit carrier and the component is filled with an underfill material.

13. The method as claimed in claim 12, further comprising introducing the underfill material into the gap in a region outside the recess.
